(19) United States
(12) Patent Application Publication
(10) Pub. No.: US 2015/0136215 A1
(43) Pub. Date: May 21, 2015

(54) SOLAR CELL CONTACTS AND METHOD OF FABRICATING SAME

(71) Applicant: TSMC SOLAR LTD., Taichung City (TW)

(72) Inventors: Chia-Hung TSAI, Kaohsiung City (TW); Tzu-Huan CHENG, Kaohsiung City (TW)

(73) Assignee: TSMC SOLAR LTD., Taichung City (TW)

(21) Appl. No.: 14/085,828

(22) Filed: Nov. 21, 2013

(51) Int. Cl. H01L 31/0224; H01L 31/0232; H01L 31/18

(52) U.S. Cl. CPC H01L 31/022441; H01L 31/18; H01L 31/02327
USPC 136/256; 438/72; 438/98

(57) ABSTRACT

A solar cell device and a method of fabricating the same is described. The solar cell includes a back contact, an absorber over the back contact, and a front contact over the absorber. The back contact includes a back electrode layer and a graphene layer.

### TECHNICAL FIELD

The disclosure relates to photovoltaic solar cells and modules and methods of fabricating the same. More particularly, the disclosure relates to solar cell substructures, such as those including back contacts, with improved device performance.

### BACKGROUND

Solar cells are electrical devices for direct generation of electrical current from sunlight by the photovoltaic (PV) effect. Solar cells include absorber layers between front and back contact layers. The absorber layers absorb light for conversion into electrical current. The front and back contact layers assist in light trapping and photo-current extraction and provide electrical contacts to the solar cell. The back contact layer contacts the absorber layer on the side opposite the site of light illumination. A plurality of solar cells can be connected in series by respective interconnect structures to form a solar cell module. A plurality of modules can be connected to form an array.

Due to the growing demand for clean sources of energy, the manufacture of solar cells has expanded dramatically in recent years and continues to expand. Various types of solar cells and solar cell substructures exist and continue to be developed in efforts to improve the performance of solar cells, modules, and systems.

### BRIEF DESCRIPTION OF THE DRAWING

The present disclosure is best understood from the following detailed description when read in conjunction with the accompanying drawings. It is emphasized that, according to common practice, the various features of the drawings are not necessarily to scale. On the contrary, the dimensions of the various features are arbitrarily expanded or reduced for clarity. Like numerals denote like features throughout the specification and drawing.

FIG. 1 is a cross section of a solar cell as described herein.

FIG. 2 is a schematic cross section view of a back contact and absorber for a solar cell as described herein.

FIG. 3 is a schematic cross section view of a back contact and absorber for a solar cell as described herein.

FIG. 4 is a schematic cross section view of a back contact and absorber for a solar cell as described herein.

FIG. 4A is a schematic cross section view of an exemplary back contact and absorber of FIG. 4.

FIG. 5 is a schematic cross section view of a back contact and absorber for a solar cell as described herein.

FIG. 6 is a flow chart of a method of fabricating a solar cell as described herein.

FIG. 7 is a flow chart of a method of fabricating a solar cell as described herein.

### DETAILED DESCRIPTION

In the description, relative terms such as “lower,” “upper,” “over” “above,” “below,” “up,” “down,” “top” and “bottom” as well as derivatives thereof (e.g., “downwardly,” “upwardly,” etc.) should be construed to refer to the orientation as then described or as shown in the drawing under discussion. These relative terms are for convenience of description and do not require that the device be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

The disclosure provides for improved photovoltaic solar cell devices and methods for fabricating the devices and substructures. Series resistance (Rs) and short circuit current density (J_{SC}) are dominant factors for power improvement, and the disclosure provides for thin film solar cells with improved Jsc and lower Rs, resulting in enhanced module efficiency. Although particular examples of thin film solar cells are described below, the structures and methods described herein can be applied to a broad variety of thin film solar cells, including chalcopyrite-based solar cells, such as Cu(In,Ga)Se₂ (CIGS), CuInSe₂, CuGaSe₂, Cu(In,Ga)(Se,S)₂ and the like, amorphous silicon thin film, cadmium telluride (CdTe) with pn junction, p-i-n stricture, MIS structure, multi-junction, or the like.

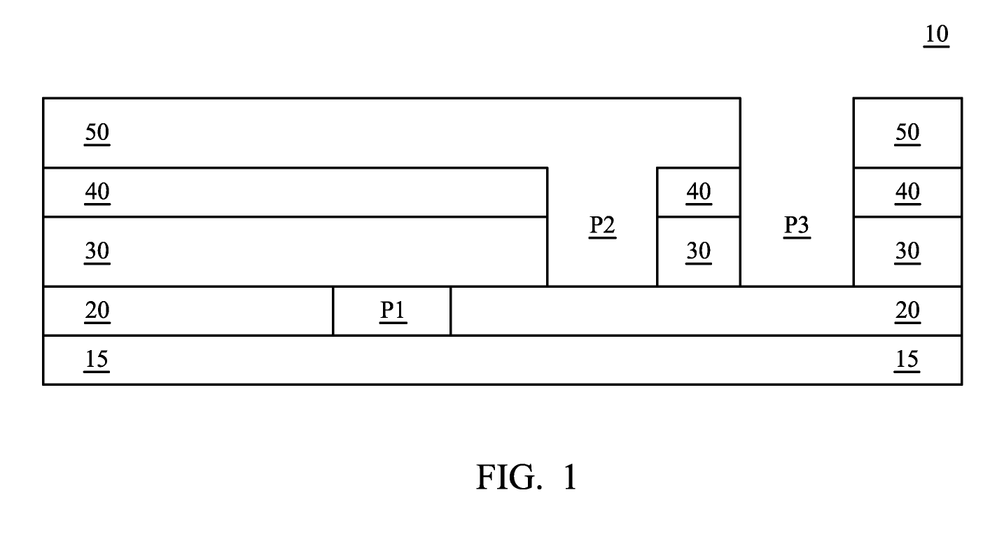

FIG. 1 shows a solar cell device 10 according to the disclosure. The solar cell 10 includes a back contact 20, an absorber 30 over the back contact 20, and a front contact 50 over the absorber 30. In some embodiments, the solar cell 10 includes a substrate 15, the back contact 20 over the substrate 15, the absorber 30 over the back contact 20, a buffer layer 40 over the absorber 30, and a front contact 50 over the buffer layer 40.

In some embodiments, the substrate 15 can include glass (e.g., soda lime glass or sodium-free (high strain point) glass), a flexible metal foil or polymer (e.g., polyimide, polyethylene terephthalate (PET), polyethylene naphthalene (PEN)), or other suitable substrate materials.

In some embodiments, the back contact 20 is an integrated back contact 20 including a back electrode layer 21 integrated with a graphene layer 25. Graphene is an allotrope of carbon, and the carbon atoms are arranged in a hexagonal pattern. The graphene layer 25 includes graphene or compounds including graphene, e.g., graphene oxide. In some embodiments, the graphene layer has a thickness ranging from about 1 nm to 100 nm. As used herein, the term “about” with respect to thickness includes minor deviations from the nominal value. For example, deviations of plus or minus 1 nm, or plus or minus 2 nm, or plus or minus 5 nm. In some embodiments, the graphene layer 25 can have a low Rs. For example, the graphene layer 25 can have a resistivity ranging from about 10⁻⁶ Ω·cm to about 10⁻⁴ Ω cm or the graphene layer 25 can have a resistivity ranging from about 10⁻⁶ Ω·cm to about 10⁻⁵ Ω·cm.

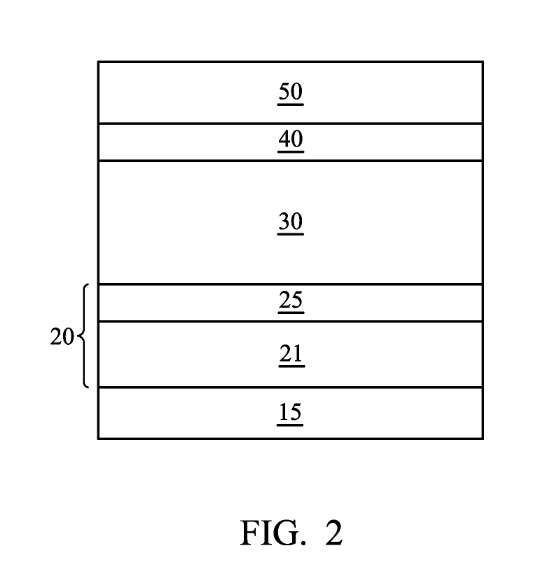

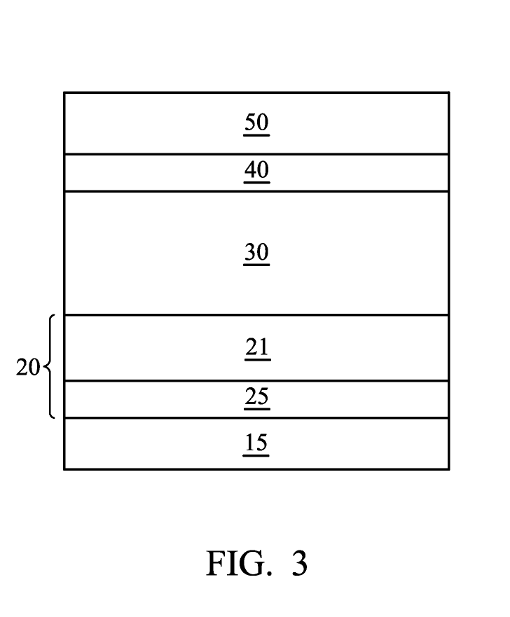

As used herein, the term “integrated” refers to the graphene layer 25 being adjacent or connected to the back electrode layer 21 to form the back contact 20. FIGS. 2-5 show various configurations for the graphene layer 25 and back electrode layer 21 in a solar cell 10. For brevity and ease of illustration, the scribe lines P1-P3 are not shown in FIGS. 2-5. In some embodiments as shown in FIG. 2, the graphene layer 25 is integrated with the back electrode layer 21 along an upper surface of the back electrode layer. In some embodiments as shown in FIG. 3, the graphene layer 25 is integrated with a lower surface of the back electrode layer 21. In other embodiments (not shown), the graphene layer 25 is integrated with a portion of the upper or lower surfaces of the back electrode layer 21, or within the back electrode layer 21.

The back electrode layer 21 includes a suitable conductive material, such as metals and metal precursors. In some embodiments, the back electrode layer 21 can include molybdenum (Mo), platinum (Pt), gold (Au), nickel (Ni), or copper (Cu). In other embodiments, a material with a higher reflectivity can be selected for the back electrode layer 21. In some embodiments, the back electrode layer 21 can include a material with a higher reflectivity than Mo. For example, Ta and Nb show a higher average reflection than Mo. Accordingly, the back electrode layer 21 can preferably include tungsten (W), tantalum (Ta), niobium (Nb), silver (Ag), chromium (Cr), vanadium (V), titanium (Ti) or manganese (Mn).

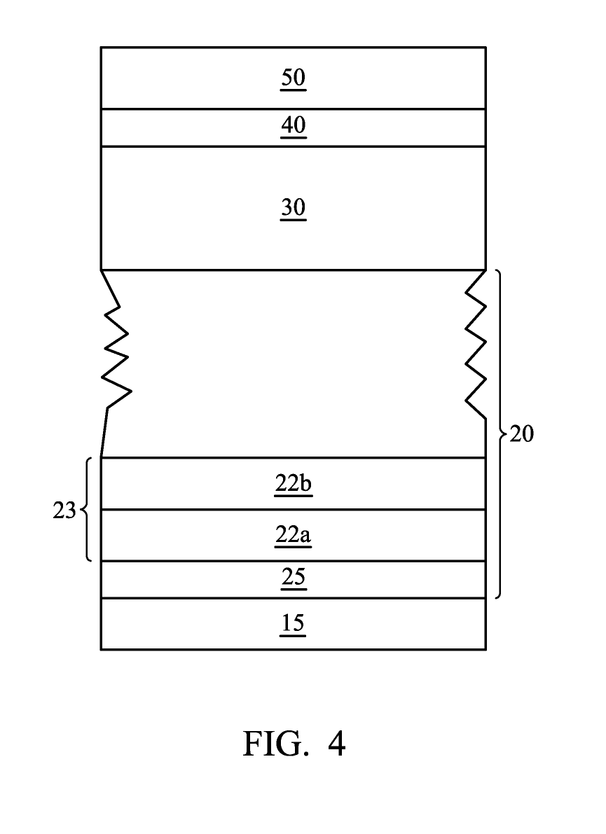

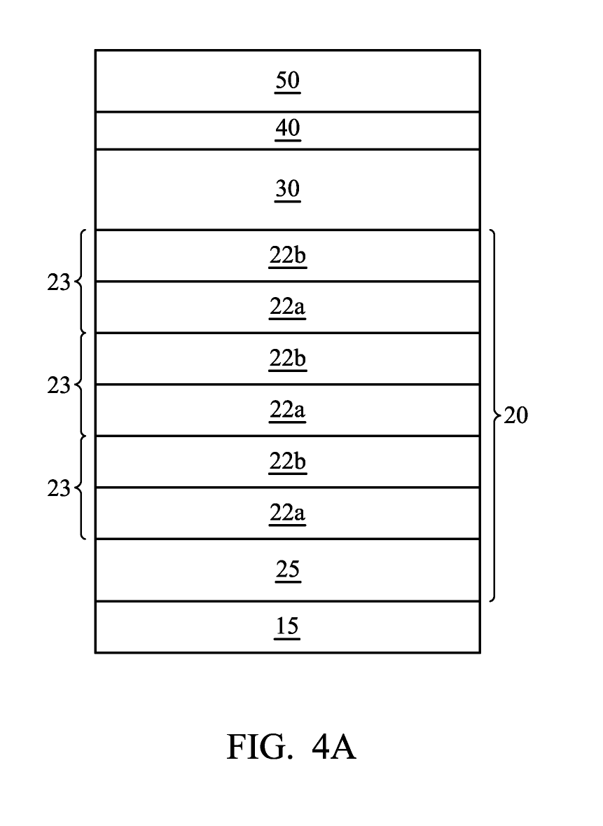

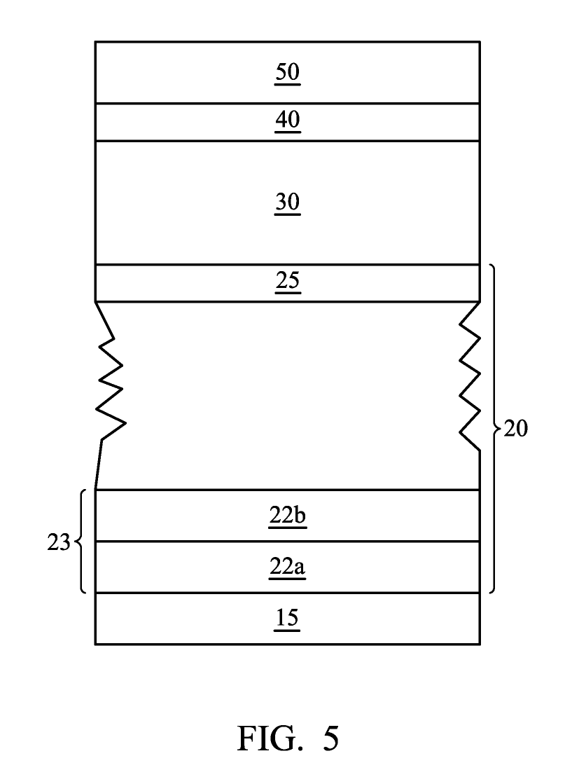

In some embodiments as shown in FIGS. 4-5, the back electrode layer 21 includes stacked layers 22 forming a distributed Bragg reflector (DBR). The stacked layers 22 can include multiple layers of alternating materials 22a, 22b with varying refractive index, or by periodic variation of some characteristic (such as height) of a dielectric waveguide, resulting in periodic variation in the effective refractive index in the guide. Each DBR layer boundary causes a partial reflection of an optical wave. For waves whose wavelength is close to four times the optical thickness of the layers, the many reflections combine with constructive interference, and the layers act as a high-quality reflector. For example, the back electrode layer 21 can include a first DBR material 22a and a second DBR material 22b and the first and second DBR materials 22a. 22b can be stacked in pairs 23, such that the first DBR material 22a and a second DBR material 22b form alternate layers as shown in FIG. 4A. For example, the first DBR material 22a can include ZnTe and the second DBR material 22b can include ZnSe. The back electrode layer 21 can include any number of pairs 23. In some embodiments, the number of DBR layers 22 can be 2 or more, 4 or more, 6 or more, 8 or more, 10 or more, 12 or more, 16 or more, or 20 or more. In some embodiments, the number of DBR layers 22 ranges from 2 to 10 layers. The plurality of stacked DBR layers 22 can have an optical reflection of 70% or greater, 75% or greater, 80% or greater, 85% or greater, or 90% or greater. For example, the stacked DBR materials could be 20-pair ZnTe/ZnSe with reflectivity greater than 90%.

In some embodiments, the back electrode layer has a thickness ranging from about 50 nm to 2 μm. In some embodiments, the back electrode layer 21 has a resistivity ranging from about 10⁻⁴ Ω·cm to about 10⁻² Ω·cm. In other embodiments, the back electrode layer 21 has a resistivity ranging from about 10⁻⁴ Ω·cm to about 10⁻³ Ω·cm. The back electrode layer 21 can also have a higher resistivity relative to the graphene layer 25.

In some embodiments, the absorber 30 can include p-type semiconductors, such as CIGS, CdTe, CuInSe₂ (CIS), CuGaSe₂ (CGS), Cu(In,Ga)(Se,S)₂ (CIGSS), or amorphous silicon. In some embodiments, the absorber 30 has a thickness ranging from about 0.3 μm to about 8 ∥m.

In some embodiments, the buffer 40 can include n-type semiconductors, such as cadmium sulphide, zinc sulphide, zinc selenide, indium (III) sulfide, indium selenide, Zn₁₋ₓMgOₓO, (e.g., ZnO), or other suitable buffer layer materials. In some embodiments, the buffer layer 40 has a thickness ranging from about 1 nm to about 500 nm.

In some embodiments, the front contact 50 can include suitable front contact materials, such as metal oxides (e.g. indium oxide) and doped metal oxides (e.g. boron-doped zinc oxide). Examples of suitable material for the front contact 50 include but are not limited to transparent conductive oxides such as indium tin oxide (ITO), fluorine-doped tin oxide (FTO), aluminum-doped zinc oxide (AZO), gallium doped ZnO (GZO), alumina and gallium co-doped ZnO (AGZO), boron doped ZnO (BZO), and any combinations thereof. A suitable material for the front contact layer 50 can also be a composite material comprising at least one of the transparent conductive oxide (TCO) and another conductive material, which does not significantly decrease electrical conductivity or optical transparency of the front contact 50. In some embodiments, the front contact layer 50 is from about 5 nm to about 3 μm thick outside of the P2 scribe line, from about 0.5 nm to about 3 μm on side walls of the P2 scribe line, and from about 5 nm to about 3 μm on the bottom of the P2 scribe line (directly on the back contact layer 20).

As shown in FIG. 1, the solar cell 10 also includes interconnect structures that include three scribe lines, referred to as P1, P2, and P3. The P1 scribe line extends through the back contact layer 20 and is filled with the absorber layer material. The P2 scribe line extends through the buffer layer 40 and the absorber layer 30 and is filled with the front contact layer material. The P3 scribe line extends through the front contact layer 50, buffer layer 40 and absorber layer 30.

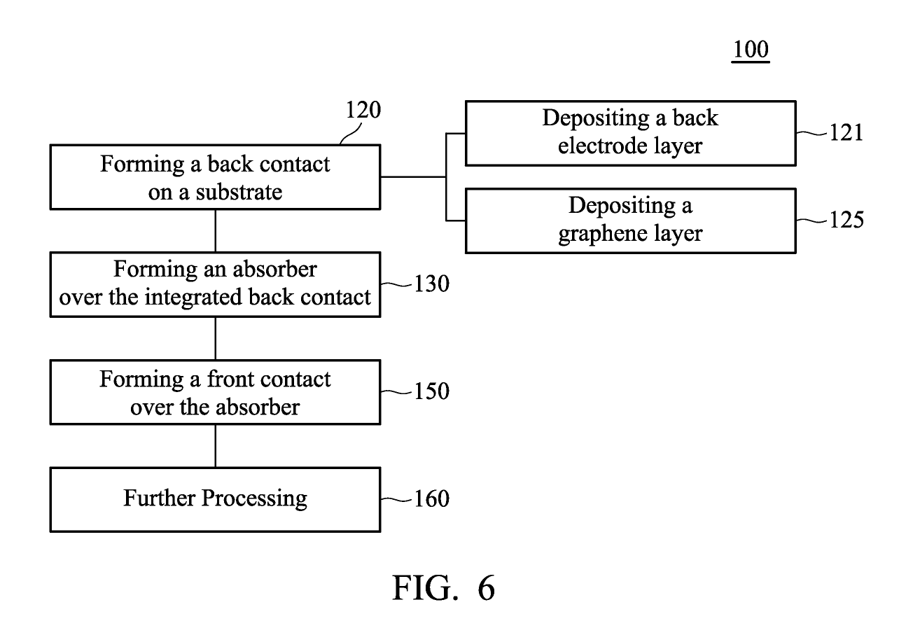

In accordance with some embodiments, FIG. 6 is a flowchart describing a broad method 100 for fabricating the solar cell 10. The back contact 20 is formed on a substrate 15 at step 120. In some embodiments, the back contact layer 20 can deposited by physical vapor deposition (PVD), for example sputtering, of a metal such as Mo, Ta or W over the solar cell substrate 15.

Step 120 for forming a back contact 20 can include depositing the back electrode layer 21 at substep 121 and depositing the graphene layer 25 at substep 125. At substep 121, the back electrode layer 21 can be deposited by PVD (e.g., sputtering), chemical vapor deposition (CVD), atomic layer deposition (ALD), or other suitable techniques for thin film deposition. At substep 125, the graphene layer 25 can be deposited by PVD (e.g., spray or spin coating), CVD, ALD, or other suitable techniques for graphene deposition. In some embodiments, the depositing steps 121, 125 are performed in a sequence including depositing the back electrode layer 121 before depositing the graphene layer 125. In other embodiments, the graphene layer can be deposited 125 before the back electrode layer is deposited 121. In other embodiments, the graphene layer can be deposited 125 before the back electrode layer is deposited 121 and another graphene layer can be deposited 125 after the back electrode layer is deposited 121

In embodiments with the back electrode layer 21 forming a DBR 22, the step 121 of depositing the back electrode layer 20 includes depositing a plurality of DBR layers 23. In some embodiments, the depositing steps 121 are performed in a sequence including depositing a first DBR material 22a over the substrate and depositing a second DBR material 22b over the first DBR material. The sequence, i.e. first DBR material 22a then second DBR material 22b, can also be repeated to form multiple sets 25 of layer 22, as shown in FIGS. 4-5. The sequence can be repeated at least once to form 4 DBR layers 23, at least twice to form 6 DBR layers, at least four times to form 10 DBR layers, or five or more times.

At step 130, the absorber 30 is formed over the back contact 20. In some embodiments, the absorber 30 comprises CIGS. In some embodiments, a plurality of CIGS precursors are sputtered onto the back contact layer 20. In some embodiments, the CIGS precursors include Cu/In, CuGa/In and/or CuInGa, applied by sputtering. The absorber layer material fills the P1 scribe line. Following the sputtering of these precursors, selenization is performed.

A step 150, the front contact 50 is formed over the absorber 30. In some embodiments, the front contact layer 50 is i-ZnO or AZO applied by sputtering. In other embodiments, the front contact layer 50 is BZO applied by metal organic chemical vapor deposition (MOCVD). The front contact layer material conformally coats the side and bottom walls of the P2 scribe line.

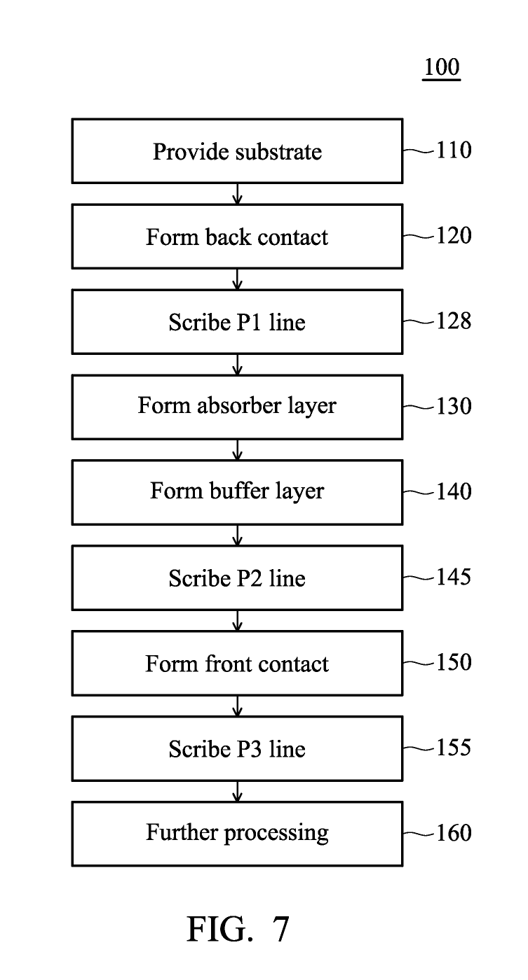

In some embodiments as shown in FIG. 7, the method 100 can also include additional steps. At step 110, a substrate 15 can be provided. At step 120, a back contact 20 can be formed over the substrate 15 as described above. At the conclusion of back contact deposition, a P1 scribe line is formed (e.g., scribed or etched) through the back contact at step 128. At step 130, an absorber 30 can be formed over the back contact 20, filling the P1 line.

At step 140, a buffer layer 40 can be formed over the absorber 30. For example, in some embodiments, a buffer layer 40 of CdS, ZnS or InS is formed by chemical bath deposition (CBD). In other embodiments, the buffer layer 40 is deposited by sputtering or ALD. Following the deposition of the buffer layer 40, the P2 scribe line is formed (e.g., scribed or etched) through the absorber layer 30 and buffer layer 40 at step 145.

At step 150, the front contact 50 can be formed over the buffer layer 40 as described above. Following deposition of the front contact layer 50, the P3 scribe line is formed (e.g., scribed or etched) through the front contact 50, buffer layer 40, and absorber 30 at step 155.

In some embodiments at step 160, the solar cell can undergo additional processing operations to complete the device and/or couple to other solar cells to form solar modules. For example, further processing may include EVA/butyl applications, lamination, back end processing, and module formation. Solar modules can, in turn, be coupled to other solar modules in series or in parallel to form an array.

The solar cell according to the disclosure provides improved electron transportation, e.g. J_{SC} and R_{S}. Generally, J_{SC} is limited by CIGS absorption at the long wavelength region (e.g., near the band gap). However, the integrated back contact described herein allows further tuning of the reflectance with higher reflectance materials, improving J_{SC}, while preventing or reducing induced high R_{S} for the back contact. In particular, the integrated back contact reduces the resistance loss at the back contact, reducing not only R_{S} but also the fill factor.

In summary, the methods for fabricating solar cell devices and substructures boosts solar module efficiency by combining high reflection and low resistivity for the integrated back contact. The integrated back contact provides improved R_{S} and J_{SC} for greater device performance. Additionally, the efficient and effective methods can be easily implemented in existing solar cell fabrication processes. For example, the methods are easy to integrate with current CIGSS production lines. As such, the disclosed methods can provide significantly improved devices at a low additional cost.

In some embodiments, a solar cell is provided. The solar cell includes a back contact with a back electrode layer and at least one graphene layer, an absorber over the back contact, and a front contact over the absorber.

In some embodiments, the graphene layer is over the back electrode layer.

In some embodiments, the graphene layer is below the back electrode layer.

In some embodiments, the graphene layer has a resistivity ranging from about 10⁻⁶ Ω·cm to about 10⁻⁴ Ω·cm.

In some embodiments, the graphene layer has a thickness ranging from 1 nm˜100 nm.

In some embodiments, the back electrode layer includes a metal.

In some embodiments, the back electrode layer has a resistivity ranging from about 10⁻⁴ Ω·cm to about 10⁻² Ω·cm.

In some embodiments, the back electrode layer forms a DBR.

In some embodiments, the back electrode layer includes a plurality of stacked DBR layers.

In some embodiments, the plurality of stacked DBR layers include an even number of layers ranging from 2 to 10 layers.

In some embodiments, the plurality of stacked DBR layers have an optical reflection of 80% or greater.

In some embodiments, a method for fabricating a solar cell is provided. The method includes forming a back contact on a substrate by depositing a back contact layer and a graphene layer over the substrate, forming an absorber over the back contact, and forming a front contact over the absorber.

In some embodiments, the back electrode layer includes a metal having a higher resistivity than Mo.

In some embodiments, the depositing steps are performed in a sequence including, in order, depositing the back electrode layer, and depositing the graphene layer over the back contact layer.

In some embodiments, the depositing steps are performed in a sequence including, in order, depositing the graphene layer, and depositing the back electrode layer over the graphene layer.

In some embodiments, the step of depositing the back electrode layer includes depositing a plurality of DBR layers over the substrate.

In some embodiments, the step of depositing the DBR layers step includes depositing a first DBR material over the substrate and depositing a second DBR material over the first DBR material.

In some embodiments, the step of depositing the DBR layers step is performed in a sequence including, in order, depositing a first DBR material over the substrate, depositing a second DBR material over the first DBR material, and repeating the sequence at least once.

In some embodiments, a method for fabricating a solar cell is provided. The method includes providing a substrate, forming a back contact over the substrate by depositing a back electrode layer and a graphene layer over the substrate, forming an absorber over the back contact, forming a buffer over the absorber, and forming a front contact over the buffer.

In some embodiments, the graphene layer is in direct contact with an upper or lower surface of the back electrode layer and the graphene layer has a lower resistivity than the back electrode layer.

The descriptions of the fabrication techniques for exemplary embodiments may be performed using any suitable commercially available equipment commonly used in the art to manufacture solar cell devices, or alternatively, using future developed equipment and techniques.

The preceding merely illustrates the principles of the disclosure. It will thus be appreciated that those of ordinary skill in the art will be able to devise various arrangements which, although not explicitly described or shown herein, embody the principles of the disclosure and are included within its spirit and scope. Furthermore, all examples and conditional language recited herein are principally intended expressly to be only for pedagogical purposes and to aid the reader in understanding the principles of the disclosure and the concepts contributed by the inventors to furthering the art, and are to be construed as being without limitation to such specifically recited examples and conditions. Moreover, all statements herein reciting principles, aspects, and embodiments of the disclosure, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

Although the disclosure has been described in terms of exemplary embodiments, it is not limited thereto. Rather, the appended claims should be construed broadly, to include other variants and embodiments of the disclosure, which may be made by those of ordinary skill in the art without departing from the scope and range of equivalents of the disclosure.

What is claimed is:

1. A solar cell comprising:
a back contact comprising a back electrode layer and at least one graphene layer;
an absorber over said back contact; and
a front contact over said absorber.

2. The solar cell as in claim 1, wherein said graphene layer is over said back electrode layer.

3. The solar cell as in claim 1, wherein said graphene layer is below said back electrode layer.

4. The solar cell as in claim 1, wherein said graphene layer has a resistivity ranging from about 10⁻⁶ Ω·cm to about 10⁻⁴ Ω·cm.

5. The solar cell as in claim 1, wherein said graphene layer has a thickness ranging from 1 nm˜100 nm.

6. The solar cell as in claim 1, wherein said back electrode layer comprises a metal.

7. The solar cell as in claim 1, wherein said back electrode layer has a resistivity ranging from about 10⁻⁴ Ω·cm to about 10⁻² Ω·cm.

8. The solar cell as in claim 1, wherein said back electrode layer comprises a distributed Bragg reflector (DBR).

9. The solar cell as in claim 1, wherein said back electrode layer comprises a plurality of stacked distributed Bragg reflector (DBR) layers.

10. The solar cell as in claim 9, wherein said plurality of stacked DBR layers comprise an even number of layers ranging from 2 to 10 layers.

11. The solar cell as in claim 9, wherein said plurality of stacked DBR layers have an optical reflection of 80% or greater.

12. A method for fabricating a solar cell, comprising:
forming a back contact on a substrate by depositing a back electrode layer and a graphene layer over said substrate;
forming an absorber over said back contact; and
forming a front contact over said absorber.

13. The method as in claim 12, wherein said back electrode layer comprises a metal having a higher resistivity than Mo.

14. The method as in claim 12, wherein said depositing steps are performed in a sequence comprising, in order:
(a) depositing said back electrode layer; and
(b) depositing said graphene layer over said back contact layer.

15. The method as in claim 12, wherein said depositing steps are performed in a sequence comprising, in order:
(a) depositing said graphene layer; and
(b) depositing said back electrode layer over said graphene layer.

16. The method as in claim 12, wherein said step of depositing said back electrode layer comprises depositing a plurality of distributed Bragg reflector (DBR) layers over said substrate.

17. The method as in claim 16, wherein said step of depositing said DBR layers comprises:
(a) depositing a first DBR material over said substrate; and
(b) depositing a second DBR material over said first DBR material.

18. The method as in claim 17, wherein said depositing steps (a) and (b) are repeated at least once.

19. A method for fabricating a solar cell, comprising:
providing a substrate;
forming a back contact over said substrate by depositing a back electrode layer and a graphene layer over said substrate;
forming an absorber over said back contact;
forming a buffer over said absorber; and
forming a front contact over said buffer.

20. The method as in claim 19, wherein said graphene layer is in direct contact with an upper or lower surface of said back electrode layer; and
said graphene layer has a lower resistivity than said back electrode layer.
